(19) United States
(12) Patent Application Publication
(10) Pub. No.: US 2026/0143660 A1
(43) Pub. Date: May 21, 2026

(54) GATE-CUT STRUCTURE WITH AIR GAP FOR ISOLATION IN SEMICONDUCTOR DEVICES

(71) Applicant: Taiwan Semiconductor Manufacturing Company, Ltd., Hsin-Chu (TW)

(72) Inventors: Yung-Ting Chang, New Taipei City (TW); Jui-Lin Chen, Taipei City (TW); Chih-Hsuan Chen, Hsinchu (TW); Chen-Ming Lee, Yangmei City (TW); Yu-Bey Wu, Hsinchu City (TW)

(21) Appl. No.: 19/183,645

(22) Filed: Apr. 18, 2025

Related U.S. Application Data
(60) Provisional application No. 63/721,783, filed on Nov. 18, 2024.

(51) Int. Cl. H10B 10/00; H01L 21/764; H10D 30/00; H10D 30/01; H10D 30/43; H10D 62/10; H10D 64/27

(52) U.S. Cl. CPC H10B 10/12; H10D 30/014; H10D 30/0191; H10D 30/43; H10D 30/502; H10D 62/121; H10W 10/021; H10W 10/20; H10D 64/518

(57) ABSTRACT

A method of fabricating a semiconductor device includes forming a first active region and a second active region over a substrate, depositing an isolation structure between the first and second active regions, forming a gate structure across the first active region and the second active region, forming a trench dividing the gate structure into a first segment and a second segment, depositing a dielectric feature in the trench, thinning the substrate and the isolation structure to expose a bottom surface of the dielectric feature, selectively removing a surface layer of the dielectric feature to form an air gap, and depositing a seal layer capping the air gap.

### PRIORITY DATA

This application claims the benefit of U.S. Provisional Application No. 63/721,783, filed Nov. 18, 2024, which is hereby incorporated by references in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

As device scaling continues, advancements in IC processing and manufacturing are required to address increased fabrication complexity. For instance, various methods have been developed to form isolation structures that segment gate structures. While existing isolation structures are generally adequate in isolating gate structure segments, they remain inadequate in certain aspects, necessitating further improvements.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a simplified top-down layout view of a semiconductor device with gate-cut structures, according to one or more aspects of the present disclosure.

FIG. 2 is a flow chart of a method of fabricating the semiconductor device as shown in FIG. 1, according to one or more aspects of the present disclosure.

FIGS. 3, 4, 5, and 6 provide perspective views of a semiconductor device at various stages of the method of FIG. 2, according to one or more aspects of the present disclosure.

FIGS. 7, 8, 9, 10, 11, 12, 13, 14, 15, 16, 17, 18, 19, and 20 provide cross-sectional views of a semiconductor device at various stages of the method of FIG. 2, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to semiconductor devices and fabrication methods, and more particularly to fabricating multi-gate devices with isolation structures “cutting” metal gate stacks of the multi-gate devices into shorter sections (segments). Such isolation structures may also be referred to as cut-metal-gate (CMG) structures or gate-cut structures. Metal gate stacks in multi-gate devices can be formed as long gate structures extending across multiple active regions (e.g., fin regions) of multiple field effect transistors (FETs). Once the gate structures are formed, a patterning process can “cut” one or more of the long gate structures into shorter sections. In other words, the patterning process can remove redundant gate portions of the one or more long gate structures to form one or more isolation trenches (also referred to as “CMG trenches”) between the FETs and separate the long gate structures into shorter sections. This process is referred to as a CMG process. Subsequently, the isolation trenches formed between the separated sections of the long gate structures can be filled with one or more dielectric materials to form isolation structures as the gate-cut structures. For example, the dielectric materials may include a liner layer with a relatively high dielectric constant and a filler layer with a relatively low dielectric constant, forming a hybrid isolation structure that electrically isolates the separated gate structure sections of adjacent multi-gate devices. However, the liner layer increases the effective dielectric constant of the gate-cut structure, thereby increasing parasitic capacitance between adjacent features. Embodiments of the present disclosure provide a backside manufacturing process for partially or fully removing at least the high-k liner layer from a backside of the gate-cut structure to form an air gap, thereby reducing the effective dielectric constant of the gate-cut structure, minimizing parasitic capacitance, and improving circuit performance.

The details of the structure and fabrication methods of the present disclosure are described below in conjunction with the accompanied drawings, which illustrate a process of making multi-gate transistors, particularly gate-all-around (GAA) transistors, according to some embodiments. A GAA transistor refers to a transistor having vertically-stacked horizontally-oriented channel layers (also referred to as channel members or nanostructures), such as in the form of nanowires and/or nanosheets. GAA transistors are promising candidates to take CMOS to the next stage of the roadmap due to their better gate control ability, lower leakage current, and fully field effect transistor (FET) layout compatibility. For the purposes of simplicity, the present disclosure uses GAA transistors as an example. Those of ordinary skill in the art should appreciate that they may readily use the present disclosure as a basis for designing or modifying other processes and structures (such as FinFET transistors) for carrying out the same purposes and/or achieving the same advantages of the embodiments introduced herein. Further, gate-cut structures find wide applications in various circuit implementations. Presented herein are specific embodiments of a static random access memory (SRAM) circuit as an exemplary circuit that implements gate-cut structures. One or ordinary skill may recognize other examples of circuits, such as logic circuits, input/output (I/O) circuits, ring oscillators, etc., that may as well benefit from aspects of the present disclosure.

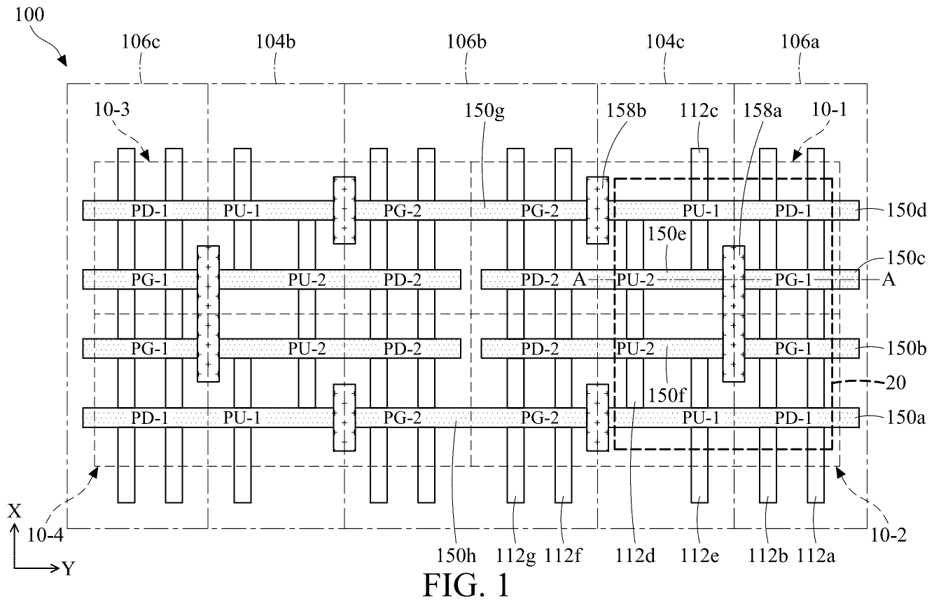

For purposes of the discussion that follows, FIG. 1 provides a simplified top-down layout view of a semiconductor structure 100 or a semiconductor device 100, according to some embodiments. Particularly, FIG. 1 illustrates a layout of an SRAM circuit that includes SRAM cells 10_1, 10_2, 10_3, and 10_4 (collectively as SRAM cells 10), in accordance with some embodiments of the disclosure. The SRAM circuit shown in FIG. 1 may be a portion of a larger SRAM cell array. In some embodiments, the transistors within the SRAM cells 10 are GAA transistors in the N-type well regions 104a and 104b and in the P-type well regions 106a through 106c. The N-type well region 104b is positioned between the P-type well regions 106b and 106c, and the N-type well region 104a is positioned between the P-type well regions 106a and 106b.

The two adjacent SRAM cells 10_1 and 10_3 are arranged in the same row of the SRAM cell array 30. The two adjacent SRAM cells 10_1 and 10_2 are arranged in the same column of the SRAM cell array. The two adjacent SRAM cells 10_3 and 10_4 are arranged in the same column of the SRAM cell array. In other words, the two adjacent SRAM cells 10_2 and 10_4 are arranged in the same row of the SRAM cell array. In FIG. 1, each of the SRAM cells 10 has the same rectangular shape/region with a width and a height, and the height is less than the width. It should be noted that the SRAM circuit shown in FIG. 1 is merely an example and is not intended to limit the SRAM cells 10 of the SRAM cell array.

In the SRAM cell 10_1, the pass-gate transistor PG-1 is formed at the cross point of the active regions 112a and 112b and the gate structure 150c on the P-type well region 106a. The pull-down transistor PD-1 is formed at the cross point of the active regions 112a and 112b and the gate structure 150d on the P-type well region 106a. The pass-gate transistor PG-2 is formed at the cross point of the active regions 112g and 112f and the gate structure 150g on the P-type well region 106b. The pull-down transistor PD-2 is formed at the cross point of the active regions 112g and 112f and the gate structure 150e on the P-type well region 106b. The pull-up transistor PU-1 is formed at the cross point of the active region 112c and the gate structure 150d on the N-type well region 104a. The pull-up transistor PU-2 is formed at the cross point of the active region 112d and the gate structure 150e on the N-type well region 104a. The active regions 112a through 112e are collectively referred to as active regions 112. Since the active regions 112 may take the form of a fin-like shape, the pull-down transistors PD-1 and PD-2 and the pass-gate transistors PG-1 and PG-2 are also referred to as the dual-fins transistors, and the pull-up transistors PU-1 and PU-2 are also referred to as the single-fin transistors.

Various contacts and their corresponding interconnect vias may be employed to couple components in each SRAM cells 10_1 through 10_4. Through a via and a gate contact, a word line (WL) contact (not shown) may be coupled to the gate of pass-gate transistor PG-1 through the gate structure 150c, and another word line contact WL is coupled to the gate of pass-gate transistor PG-2 through the gate structure 150f. Likewise, a bit line (BL) contact (not shown) is coupled to the drain of pass-gate transistor PG-1, and a complementary bit line contact BLB is coupled to the drain of pass-gate transistor PG-2.

A power source contact (not shown) coupled to the power supply node VDD is coupled to the source of the pull-up transistor PU-1, and another power source contact (not shown) coupled to the power supply node VDD is coupled to the source of the pull-up transistor PU-2. A ground contact (not shown) coupled to the ground VSS is coupled to the source of the pull-down transistor PD-1, and another ground contact (not shown) coupled to the ground VSS is coupled to the source of the pull-down transistor PD-2.

In such embodiments, the SRAM cell 10_2 is a duplicate cell for the SRAM cell 10_1 but flipped over the Y direction. Furthermore, the SRAM cell 10_3 is a duplicate cell for the SRAM cell 10_1 but flipped over the X direction. Moreover, the SRAM cell 10_4 is a duplicate cell for the SRAM cell 10_3 but flipped over the Y direction. The common contacts (e.g., BL, VDD, and VSS), are combined to save space.

The gate structure 150e is shared by the pull-up transistor PU-2 and the pull-down PD-2 of the SRAM cell 10_1. A dielectric structure 158a is formed over a boundary (or a junction, interface) between the P-type well region 106a and the N-type well region 104a, and the gate structures 150c and 150e are separated by the dielectric structure 158a. That is, the dielectric structure 158a is a gate-cut structure (or referred to as CMG structure or CMG feature) for the gate structures 150c and 150e. The gate structure 150d is shared by the pull-up transistor PU-1 and the pull-down PD-1 of the SRAM cell 10_1, and the gate structure 150g is shared by the pass-gate transistors PG-2 of the SRAM cells 10_1 and 10_3. A dielectric structure 158b is formed over a boundary (or a junction, interface) between the P-type well region 106b and the N-type well region 104a, and the gate structures 150d and 150g are separated by the dielectric structure 158b. That is, the dielectric structure 158b is a gate-cut structure for the gate structures 150d and 150g. The dielectric structures 158a and 158b are collectively referred to as gate-cut structure 158. In some embodiments, the gate-cut structures 158 are formed by a CMG process.

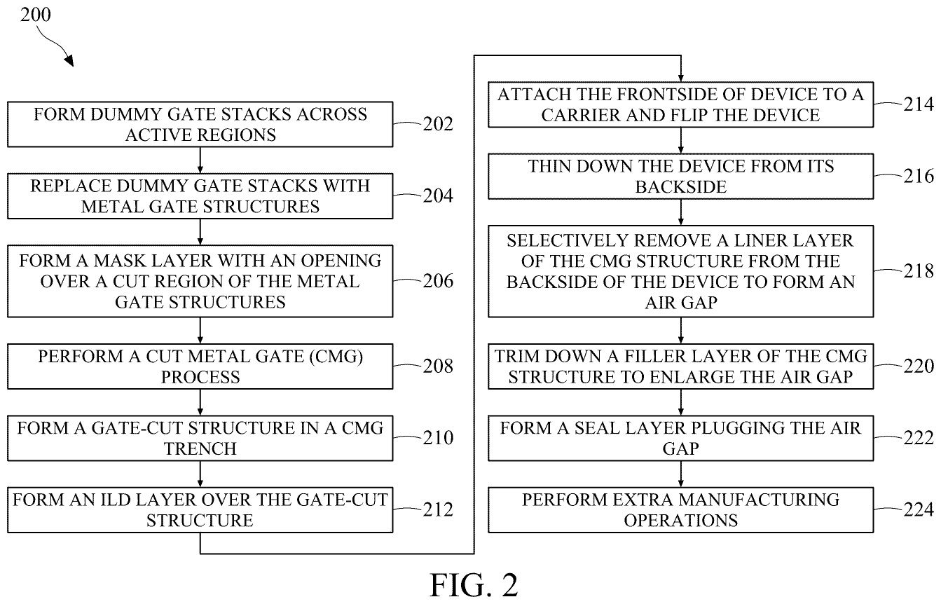

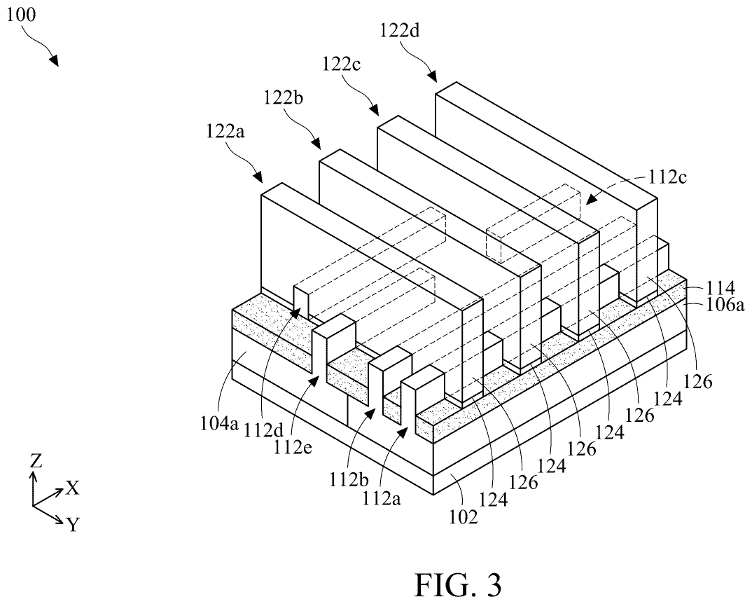

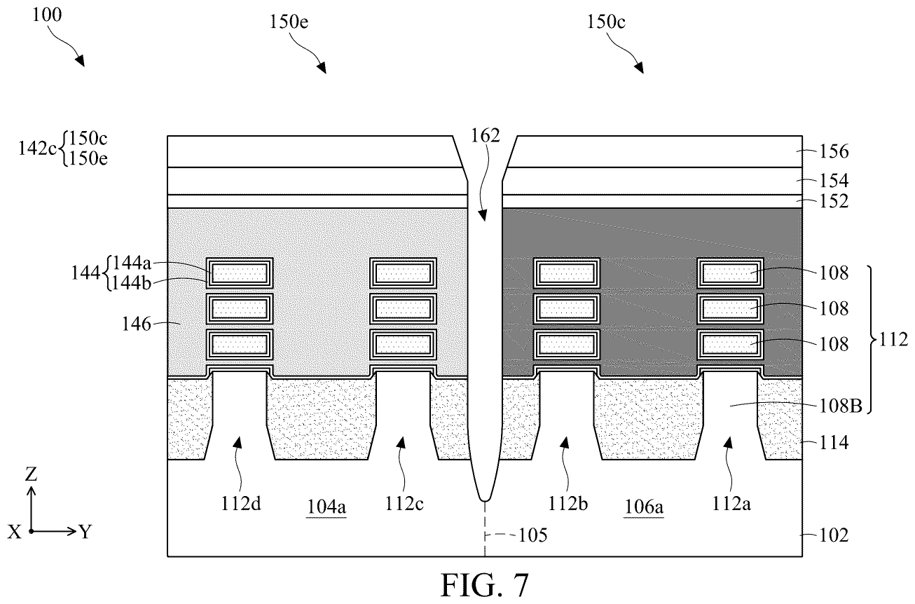

FIG. 2 illustrates a flowchart of a method 200 for forming the semiconductor structure 100, in accordance with embodiments of the present disclosure. Method 200 is merely an example and is not intended to limit the present disclosure to the specific steps shown. Additional steps may be included before, during, or after method 200, and certain steps may be modified, omitted, or reordered in different embodiments. For simplicity, not all steps are described in detail. Method 200 is further described below in conjunction with FIGS. 3-20, which represent perspective views and cross-sectional views, respectively, of a region 20 (dashed rectangular box in FIG. 1) of the semiconductor structure 100 that includes the dielectric structure 158a as an exemplary gate-cut structure, for showing various stages of manufacturing the semiconductor structure 100. Specifically, FIGS. 3-6 illustrate perspective views, and FIGS. 7-20 illustrate cross-sectional views along a cutline A-A of the semiconductor structure 100 in FIG. 1. For avoidance of doubts, the X, Y and Z directions in FIGS. 1 and 3-20 are perpendicular to one another. Throughout the present disclosure, unless expressly described otherwise, like reference numerals denote like features or steps.

Referring to FIGS. 2 and 3, method 200 includes a block 202 where dummy gate stacks 122a through 122d are formed across the active regions 112a to 112e. As show in FIG. 3, a substrate 102 includes a first-type well region 104a and a second-type well region 106a. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

The first-type well region 104a and the second-type well region 106a may be formed by doping different types of dopants in the substrate 102. In some embodiments, the first-type well region 104a is an N-type well region doped with N-type dopants, and the second-type well region 106a is a P-type well region doped with P-type dopants. In some embodiments, the first-type well region 104a includes Si, SiGe, SiGeB, Ge, InSb, GaSb, InGaSb, or the like, and the second-type well region 106a includes Si, SiP, SiC, SiPC, InP, GaAs, AlAs, InAs, InAlAs, InGaAs, or the like.

After the first-type well region 104a and the second-type well region 106a are formed, active regions 112a through 112e are formed over the substrate. More specifically, the active regions 112a and 112b are formed over the second-type well region 106a, and the active regions 112c, 112d, and 112e are formed over the first-type well region 104a in accordance with some embodiments. The active regions 112a to 112e may be formed by patterning an epitaxial stack of alternating channel layers and sacrificial layers atop the substrate 102 and a top portion of the substrate 102. For example, the active regions 112a and 112b may be formed by patterning the epitaxial stack and a top portion of the substrate 102 in the second-type well region 106a, and the active regions 112c, 112d, and 112e may be formed by patterning the epitaxial stack and a top portion of the substrate 102 in the first-type well region 104a. In addition, the active regions 112c and 112e are aligned with but separated from each other. The active regions 112c and 112e may be formed by a cut process that recesses a middle portion of an otherwise continuous active region and divides it into a first section corresponding to the active region 112c and a second section corresponding to the active region 112e. The cut process may also remove the two end portions of the active region 112d, such that the end portions of the active region 112d do not extend beyond outside gate sidewalls of the dummy gate stack 122a and 122d.

After the active regions 112a through 112e are formed, an isolation structure 114 is formed over the substrate 102, and the active regions 112a through 112e are surrounded by the isolation structure 114. The isolation structure 114 may be formed by depositing an insulating layer over the substrate 102 and recessing the insulating layer. In some embodiments, the isolation structure 114 is made of silicon oxide, silicon nitride, silicon oxynitride, fluoride-doped silicate glass (FSG), or other low-K dielectric materials. In some embodiments, the isolation structure 114 is a shallow trench isolation (STI) structure.

Next, dummy gate stacks 122a through 122d are formed across the active regions 112a to 112e and extend onto the isolation structure 114. More specifically, the dummy gate stacks 122a and 122b are formed across the active regions 112a and 112b over the second-type well region 106a and across the active regions 112d and 122e over the first-type well region 104a in accordance with some embodiments. In addition, the dummy gate stacks 122c and 122d are formed across the active regions 112a and 112b over the second-type well region 106a and across the active regions 112c and 112d over the first-type well region 104a.

In some embodiments, the dummy gate stacks 122a through 122d individually include a gate dielectric layer 124 and a gate electrode layer 126 formed over the gate dielectric layer 124. In some embodiments, the gate dielectric layer 124 is made of silicon oxide. In some embodiments, the gate electrode layer 126 is made of polysilicon. In some embodiments, the gate dielectric layer 124 covers the active regions 112a to 112e.

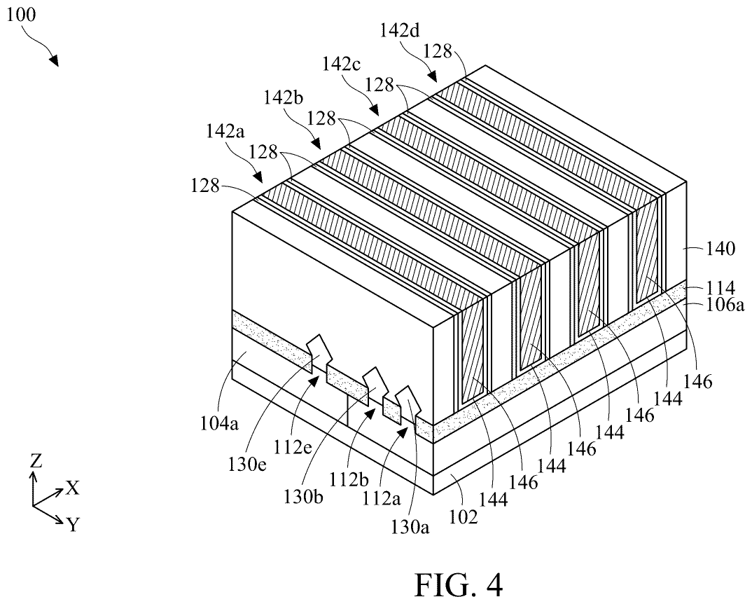

Referring to FIGS. 2 and 4, method 200 includes a block 204 where the dummy gate stacks 122a through 122d are replaced by metal gate stacks 142a through 142d in a replacement gate process. Referring to FIG. 4, after the dummy gate stacks 122a through 122d are formed, gate spacers 128 are formed on the sidewalls of the dummy gate stacks 122a through 122d. In some embodiments, the gate spacers 128 are made of silicon nitride, silicon oxide, silicon carbide, silicon oxynitride, or other applicable materials.

Next, source/drain features 130 (e.g., 130a through 130e) are formed in the active regions 112a through 112e adjacent to the dummy gate stacks 122a to 122d. More specifically, source/drain features 130a are formed in the active region 112a at opposite sides of the dummy gate stacks 122a to 122d and source/drain features 130b are formed in the active regions 112b at opposite sides of the dummy gate stacks 122a to 122d over the second-type well region 106a. In addition, source/drain features 130e are formed in the active region 112e at opposite sides of the dummy gate stacks 122a, source/drain structures 130c (not shown in FIG. 4) are formed in the active region 112c at opposite sides of the dummy gate stack 122d, and source/drain structures 130d (not shown in FIG. 4) are formed in the active region 112d at opposite sides of the dummy gate stacks 122b and 122c over the first-type well region 104a. Also as illustrated in FIG. 4, in some embodiments, in the Y-Z plane each source/drain feature 130 may include a portion overhanging the isolation structure 114.

The source/drain features 130a through 130e may be formed by recessing the active regions 112a through 112e and growing semiconductor materials in the recesses by performing epitaxial processes. The semiconductor materials may include Si, SiP, SiC, SiPC, InP, GaAs, AlAs, InAs, InAlAs, InGaAs, SiGe, SiGeB, Ge, InSb, GaSb, InGaSb, or the like.

After the source/drain structures 130a through 130e are formed, an inter-layer dielectric (ILD) layer 140 is formed around the dummy gate stacks 122a through 122d to cover the source/drain features 130a through 130e and the isolation structure 114. The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the ILD layer 140 is formed, the dummy gate stacks 122a through 122d are replaced by metal gate stacks 142a through 142d in a replacement gate process. The replacement gate process also removes the sacrificial layers from the active regions 112a through 112e, such that the channel layers in the active regions 112a through 112e remain and are wrapped around by the metal gate stacks 142a through 142d, respectively. In some embodiments, the metal gate stacks 142a through 142d individually include gate dielectric layers 144 and gate electrode layers 146. In some embodiments, the gate dielectric layers 144 include an interfacial layer and a high-k dielectric layer formed of a high-k dielectric material. In some embodiments, the gate electrode layers 146 include a work function metal layer and a metal fill layer over the work function metal layer. The work function metal layer fine tunes the proper work function values for the metal gate stacks 142a through 142d.

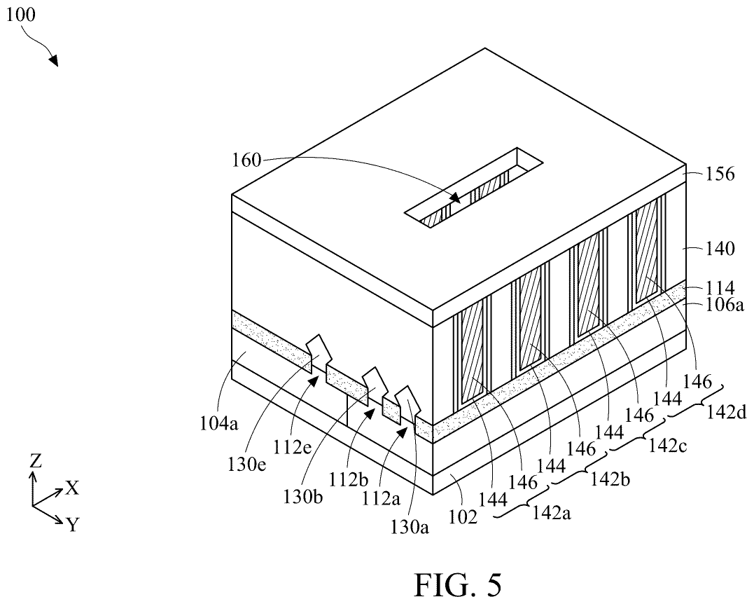

Referring to FIGS. 2 and 5, method 200 includes a block 206 where a mask layer 156 is formed to cover the metal gate stacks 142a through 142d and the ILD layer 140. In addition, the mask layer 156 includes an opening 160 exposing the portions of the metal gate stacks 142b and 142c that are designed to be cut (e.g. removed) in subsequent etching process in accordance with some embodiments. The opening 160 exposes some portions of the metal gate stacks 142b and 142c and the gate spacers 128 and the portions of the ILD layer 140 between and adjacent to the exposed portions of the metal gate stacks 142b and 142c. In some embodiments, the mask layer 156 is made of silicon nitride, silicon oxynitride, silicon oxide, titanium nitride, silicon carbide, one or more other applicable materials, or a combination thereof. The mask layer 156 may be formed by depositing a dielectric layer using a spin-on process, a CVD process, a PVD process, or other applicable processes and patterning the dielectric layer through an opening in a photoresist layer (not shown) formed over the dielectric layer.

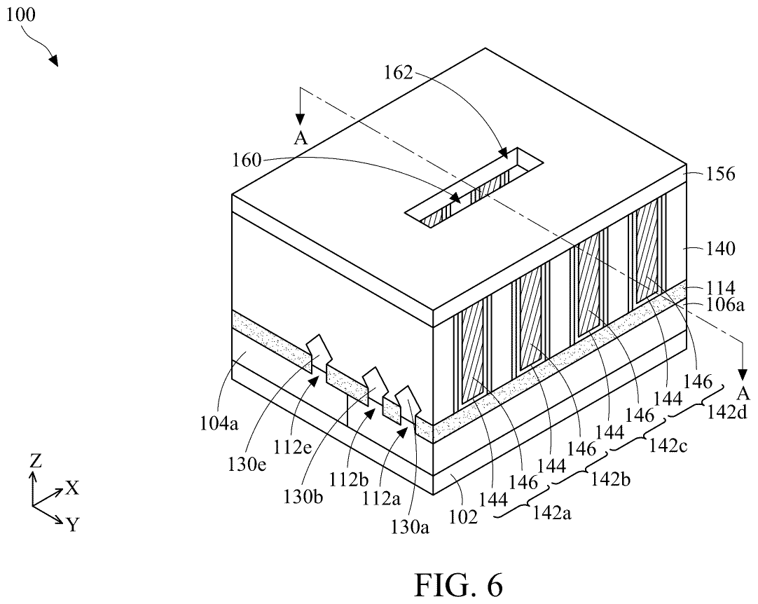

Referring to FIGS. 2 and 6, method 200 includes a block 208 where a cut-metal-gate (CMG) process is performed. Referring to FIG. 6, after the mask layer 156 is formed, the exposed portions of the metal gate stacks 142b and 142c and the exposed portions of the ILD layer 140 are etched through the opening 160 of the mask layer 156 to form a recess 162. The recess 162 is also referred to as a CMG trench. In some embodiments, the portions of the metal gate stacks 142b and 142c, the gate spacers 128, and the ILD layer 140 exposed by the opening 160 of the mask layer 156 are etched in an etching process. The etching process to remove the exposed metal gate stacks 142b and 142c may include a two-step etching process, in which the first etching step is applied before the CMG trench 162 reaches the isolation region 114 and the second etching step is applied for an over-etching into the isolation region 114 to ensure the redundant portions of the metal gate stacks 142b and 142c are removed.

FIG. 7 illustrates a cross-sectional view along the cutline A-A (shown in FIGS. 1 and 6) of the semiconductor structure 100 at the conclusion of operations at block 208, which cuts through the metal gate stack 142c along its lengthwise direction (Y direction).

The CMG trench 162 extends downwardly through the metal gate stack 142c and the isolation structure 114 and further into a top portion of the substrate 102. The CMG trench 162 divides the otherwise continuous metal gate stack 142 into a first segment 150c and a second segment 150e. The first segment 150c crosses the active regions 112a and 112b over the P-type well region 106a in forming an N-type transistor, which corresponds to the pass-gate transistor PG-1 in FIG. 1. The first segment 150c is also referred to as the gate structure 150c. The second segment 150e crosses the active regions 112c and 112d over the N-type well region 104a in forming a P-type transistor, which corresponds to the pull-up transistor PU-2 in FIG. 1. The second segment 150e is also referred to as the gate structure 150e. The CMG trench 162 extends beyond the bottom surface of the isolation structure 114 for a better isolation between the gate structures 150c and 150e. In the illustrated embodiment, the CMG trench 162 is positioned directly above the interface 105 between the well regions 104a and 106a of opposite conductivity types. Alternatively, the CMG trench 162 may be fully positioned above the well region 104a as closer to the active region 112c or fully positioned above the well region 106a as closer to the active region 112b.

Each of the gate structures 150c and 150e includes an interfacial layer 144a, a high-k dielectric layer 144b disposed on the interfacial layer 144a (collectively referred to as the gate dielectric layer 144), and a gate electrode layer 146 disposed on the high-k dielectric layer 144b. The interfacial layer 144a wraps around the channel layers 108 of the respective active regions 112 and disposed on the top surface of the fin-shaped base 108B of the respective active regions 112. The interfacial layer 144a may include a dielectric material such as silicon oxide, hafnium silicate, or silicon oxynitride. The interfacial layer 144a may be formed by chemical oxidation, thermal oxidation, atomic layer deposition (ALD), chemical vapor deposition (CVD), and/or other suitable method. In the illustrated embodiment, the interfacial layer 144a is formed by thermal oxidating semiconductor materials exposed during the replacement gate process. Therefore, the interfacial layer 144a is formed on semiconductor surfaces, such as the exposed surfaces of the channel layers 108 and the top surface of the fin-shaped base 108B, but not on dielectric surfaces, such as the top surface of the isolation structure 114.

The high-k dielectric layer 144b includes a high-k dielectric material, such as hafnium oxide. Alternatively, the gate dielectric layer may include other high-k dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. A dielectric constant of the high-k dielectric layer 144b is greater than a dielectric contact of the gate spacers 128. The high-k dielectric layer 144b may be formed by ALD, physical vapor deposition (PVD), CVD, oxidation, and/or other suitable methods. In some embodiments, the high-k dielectric layer 114b is conformally deposited as a blanket layer.

The gate electrode layer 146 includes a work function metal layer and a metal fill layer over the work function layer. The work function metal layer in the gate structure 150e is a P-type work function metal layer for the P-type transistors, and the work function metal layer in the gate structure 150c is an N-type work function metal layer for the N-type transistors. The p-type work function metal layer comprises a metal selected from, but not limited to, the group of titanium nitride, tantalum nitride, ruthenium, molybdenum, tungsten, platinum, or combinations thereof. The n-type work function metal layer comprises a metal selected from, but not limited to, the group of titanium, aluminum, tantalum carbide, tantalum carbide nitride, tantalum silicon nitride, or combinations thereof. In some embodiments, the p-type or n-type work function metal layer includes a plurality of layers deposited by CVD, PVD, and/or other suitable process. The metal fill layer includes aluminum, tungsten, cobalt, copper, and/or other suitable materials, and is formed by CVD, PVD, plating, and/or other suitable processes.

The isolation structure 114 is formed around the fin-shaped base 108B of the active regions 112. In the illustrated embodiment, the top surface of the isolation structure 114 is below the top surface of the fin-shaped base 108B and has a dishing profile due to loading effect during etching process in forming the isolation structure 114. The fin-shaped base 108B protrudes from the top portion of the substrate 102 and is at least partially embedded or buried in the isolation structure 114. In the illustrated embodiment, the edge of the dishing profile of the isolation structure 114 intersects sidewalls of the top portion of the fin-shaped base 108B.

The channel layers (also referred to as channel members or nanostructures) 108 are vertically stacked above the fin-shaped base 108B in the respective active regions 112. The channel layers 108 are formed of silicon (Si). While three (3) channel layers 108 are depicted as suspended above one fin-shaped base 108B, this is for illustrative purposes only and is not intended to be limiting beyond what is specifically recited in the claims. It can be appreciated that any number of channel layers 108 can be formed, where for example, the number of channel layers 108 depends on the desired number of channels for the GAA device. In some embodiments, the number of channel layers 108 suspended above the fin-shaped base 108B is between 2 and 10.

In the depicted embodiment, a metal layer 152 is formed over the gate electrode layer 266 of the gate structures 150e and 150c. In some embodiments, the metal layer 152 includes selectively-grown tungsten (W), although other suitable metals may also be used. In at least some examples, the metal layer 152 includes a fluorine-free W (FFW) layer. In various examples, the metal layer 152 may serve as an etch-stop layer and may also provide reduced contact resistance (e.g., to the metal layers of the gate structures). In the depicted embodiment, a capping layer 154 may further be formed over the metal layer 152. In some embodiments, the capping layer 154 includes silicon (Si). However, in some examples, the capping layer 154 may include a dielectric material such as silicon oxide, silicon nitride, silicon carbide, silicon oxynitride, combinations thereof, or another suitable material.

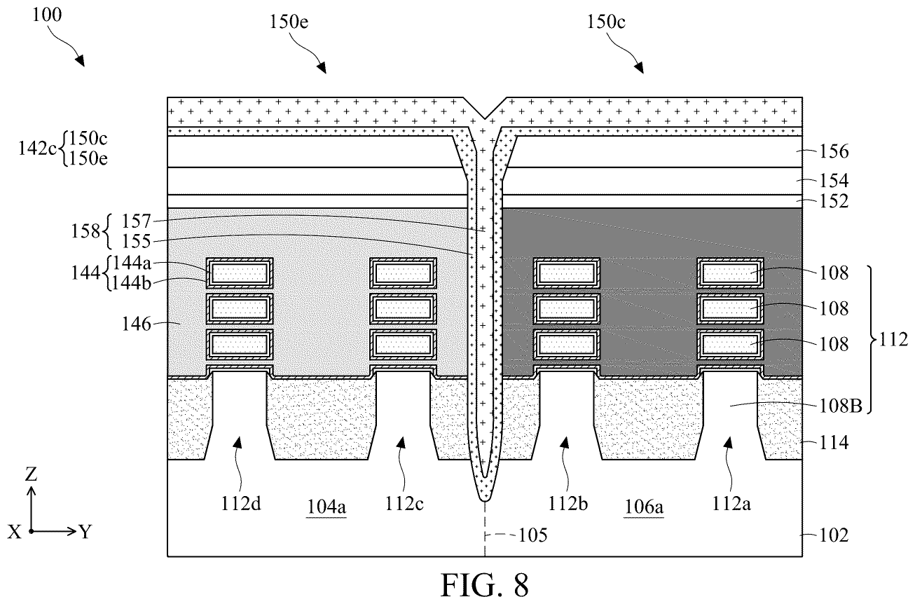

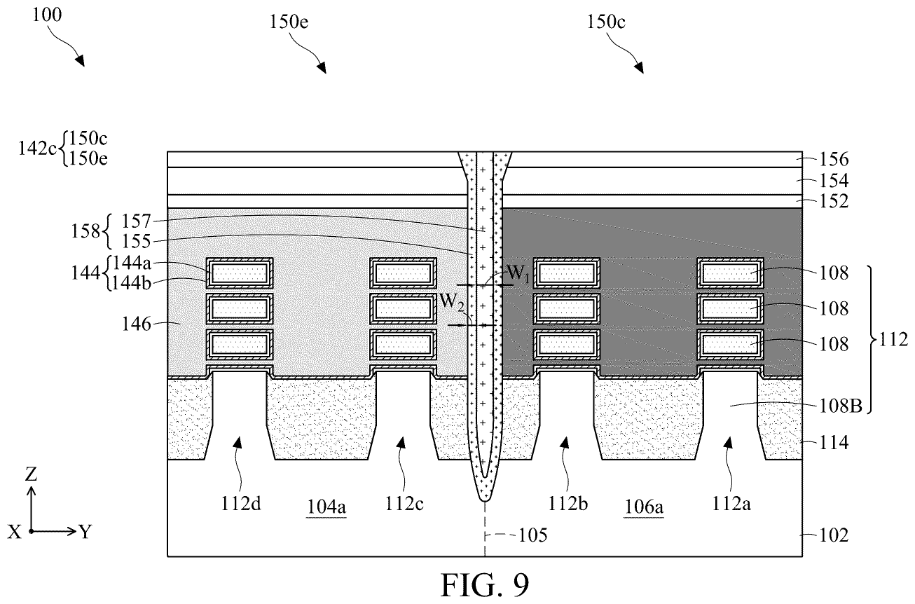

Referring to FIGS. 2 and 8-9, method 200 includes a block 210 where a CMG refill process is performed. Referring to FIG. 8, the CMG refill process is used to form dielectric layer 158 over the semiconductor structure 100, including over the mask layer 156. The dielectric layer 158 also fills the previously formed CMG trench 162 and electrically isolate the gate structures 150c and 150e. In some embodiments, the dielectric layer 158 includes a liner layer 155 and a filler layer 157 over the liner layer 155. The liner layer 155 may be a nitride layer, for example including SiN. The filler layer 157 may include SiO₂, silicon oxynitride, FSG, a low-k dielectric, combinations thereof, and/or other suitable materials. In various examples, the liner layer 155 may be conformally deposited by an ALD process, a CVD process, a PVD process, and/or other suitable process, and the filler layer 157 may be deposited by a CVD process, an SACVD process, a flowable CVD process, an ALD process, a PVD process, and/or other suitable process. After depositing the dielectric layer 158, a planarization process, such as a CMP process, may be performed to remove excess material and planarize a top surface of the semiconductor device 100. In the illustrated embodiment, the mask layer 156 may be thinned down to expose its top surface. Alternatively, the mask layer 156 may be fully removed to expose the top surface of the capping layer 154. The resultant structure after the CMP process is shown in FIG. 9. The remaining portions of the dielectric layer 158 filling the CMG trench 162 is also referred to as the CMG structure 158 or gate-cut structure 158.

The liner layer 155 has a dielectric constant higher than that of the filler layer 157 and is designed to prevent oxygen atoms in the oxygen-containing filler layer 157 from diffusing into the metal layers of the gate structures 150c and 150e, which could introduce impurities. To effectively block the diffusion of oxygen atoms, the thickness W₂ of the liner layer 155 needs to be sufficiently large, such as at least 1% of the thickness W₁ of the filler layer 157 (i.e., W₂/W₁>0.01). However, the high dielectric constant of the liner layer 155 increases the overall dielectric constant of the gate-cut structure 158, leading to higher parasitic capacitance and degraded circuit performance. To mitigate these impacts, the thickness W₂ of the liner layer 155 also needs to remain sufficiently small, such as less than 50% of the thickness W₁ of the filler layer 157 (i.e., W₂/W₁<0.5). Circuit designers would have to balance these trade-offs when selecting an appropriate thickness for the liner layer 155. As discussed in detail below, a backside process can be performed to partially or fully remove the liner layer 155 from the backside of the semiconductor structure 100, introducing an air gap between the filler layer 157 and the metal layers of the gate structures. This air gap effectively reduces the overall dielectric constant of the gate-cut structure 158. Compared to frontside removal of the liner layer 155, which is challenging to remove bottom portions of the liner layer 155 due to the high aspect ratio of the gate-cut structure 158, backside removal is more feasible. The aspect ratio is already reduced after a backside thinning process, allowing for easier liner layer removal, which will be further discussed below.

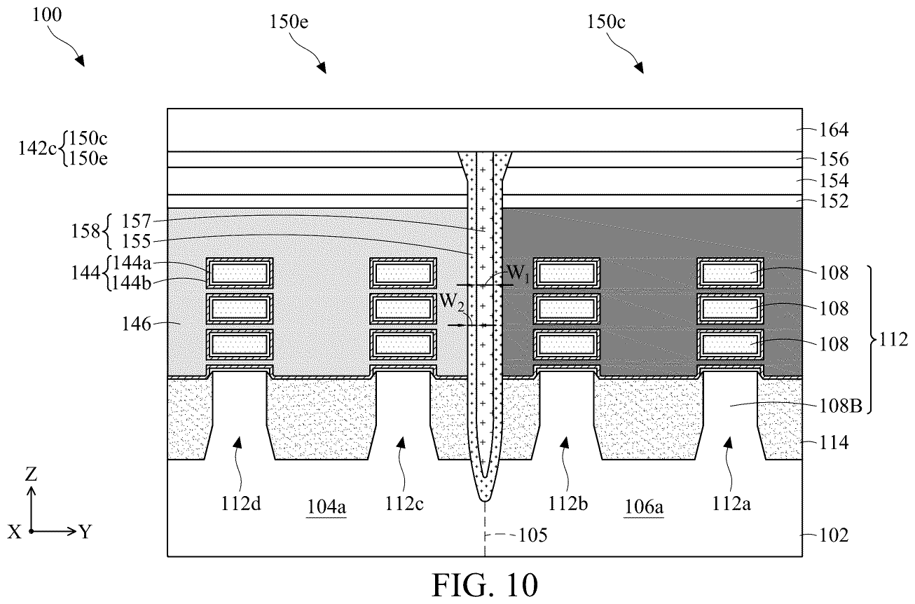

Referring to FIGS. 2 and 10, method 200 includes a block 212 where a second ILD layer 164 is deposited on the semiconductor device 100. The second ILD layer 164 covers the exposed top surfaces of the mask layer 156 and the gate-cut structure 158. In some embodiments, a thickness of the ILD layer 140 is greater than a thickness of the second ILD layer 164. In some embodiments, the second ILD layer 164 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The second ILD layer 164 may be deposited using CVD, flowable CVD (FCVD), spin-on coating, or a suitable deposition technique.

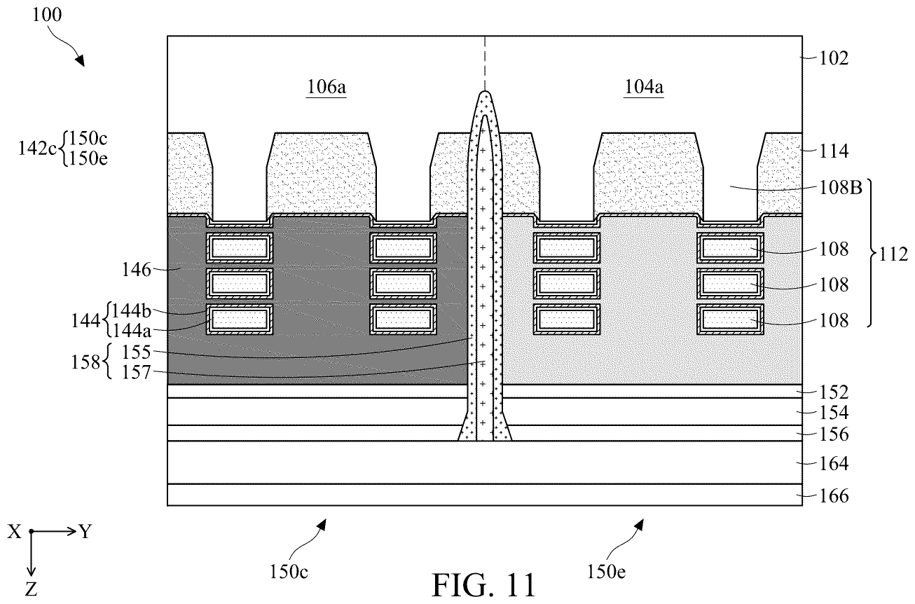

Referring to FIGS. 2 and 11, the method 200 includes a block 214 where the frontside of the semiconductor device 100 is attached to a carrier 166 and flipped up upside down. This makes the semiconductor device 100 accessible from the backside of the semiconductor device 100 for further processing. Operations at the block 214 may use any suitable attaching processes, such as direct bonding, hybrid bonding, using adhesive, or other bonding methods. Operations at block 214 may further include alignment, annealing, and/or other processes. The carrier 166 may be a silicon wafer in some embodiments.

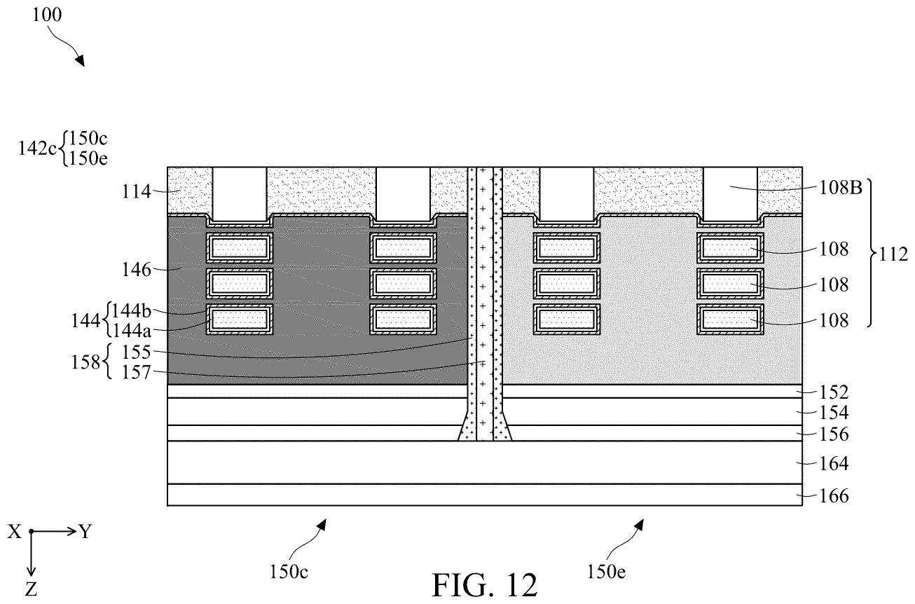

Referring to FIGS. 2 and 12, the method 200 includes a block 216 where the semiconductor structure 100 is thinned down from the backside. In some embodiments, the thinning process may involve mechanical grinding and/or chemical thinning. Initially, a substantial amount of substrate material is removed from the substrate 102 through mechanical grinding. Subsequently, a chemical thinning process is employed, during which an etching chemical is applied to the backside of the substrate 102 for further thinning, including the partial removal of the isolation structure 114. In the illustrated embodiment, once the isolation structure 114 is exposed, additional features, such as the fin-shaped base 108B and the liner layer 155 and filler layer 157 of the gate-cut structure 158 are also exposed on the backside of the semiconductor device 100.

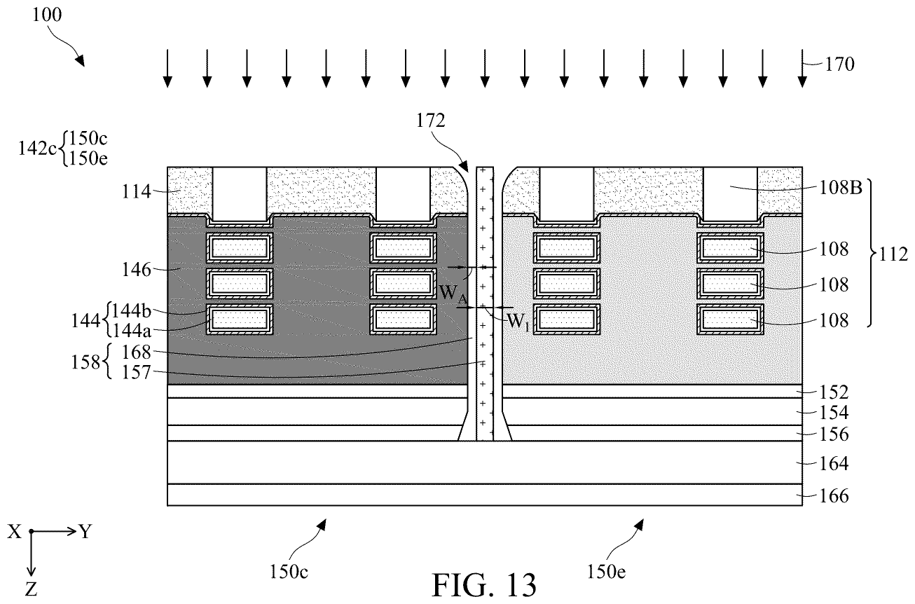

Referring to FIGS. 2 and 13, the method 200 includes a block 218 where the liner layer 155 is selectively removed from the backside of the semiconductor structure 100 to form a gap 168. An etching process 170 is performed to selectively remove the liner layer 155 without substantially etching the filler layer 157 and the isolation structure 114, the fin-shaped base 108B, or other components of the semiconductor structure 100. The gap 168 tracks the shape of the liner layer 155. The gap 168 is also referred to as the air gap 168. As used herein, the term “gap” or “air gap” is used to describe a void defined by surrounding substantive features, where a void may contain air, nitrogen, ambient gases, gaseous chemicals used in fabrication processes, or combinations thereof. Backside removal of the liner layer 155 may be more feasible than frontside removal, which may struggle to eliminate the bottom portions of the liner layer 155 due to the high aspect ratio of the gate-cut structure 158. Since the backside thinning process reduces the aspect ratio, removing the liner layer 155 becomes easier. The etching process 170 may include a dry etching process, a wet etching process, other suitable processes, or combinations thereof. For example, the etching process 170 is a wet etching process that utilizes an acid such as phosphoric acid (H₃PO₄), other suitable acids, or combinations thereof. In another embodiment, the etching process 242 is a dry etching process utilizing a halogen-based etchant such as a fluorine-based etchant (e.g., CF₄, SF₆, CH₂F₂, CHF₃, C₂F₆, HF), or other suitable etchant. In the depicted embodiment, due to limited etching contrast, sidewalls of the isolation structure 114 facing the filler layer 157 may suffer some etching lost and exhibit a tapering profile at the conclusion of operations at the block 218. That is, the opening 172 of the air gap 168 may have a larger width than a width of a middle portion (denoted as W_{A}) of the air gap 168.

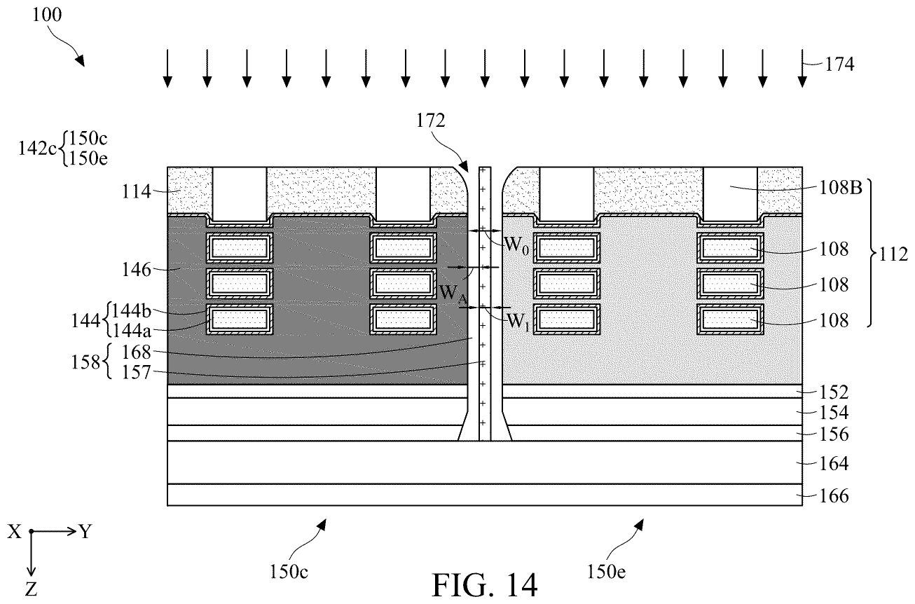

Referring to FIGS. 2 and 14, the method 200 includes a block 220, where the filler layer 157 is further reduced in width W₁. A trimming process 174, which may be different from the previous etching process 170 in etchants applied, selectively thins the filler layer 157 without substantially etching the isolation structure 114, the fin-shaped base 108B, or other components of the semiconductor structure 100. Since the dielectric constant of the air gap 168 (approximately 1) is lower than that of the filler layer 157, the trimming process enlarges the air gap 168 in its width W_{A}, thereby further reducing the overall effective dielectric constant of the gate-cut structure 158. Upon completing block 220, the ratio of W_{A} to the width W₀ of the gate-cut structure 158 may range from about 0.2 to 1 (0.2<W_{A}/W₀≤1). In some embodiments, block 220 may be optional, allowing the method 200 to bypass it and proceed directly to subsequent operations.

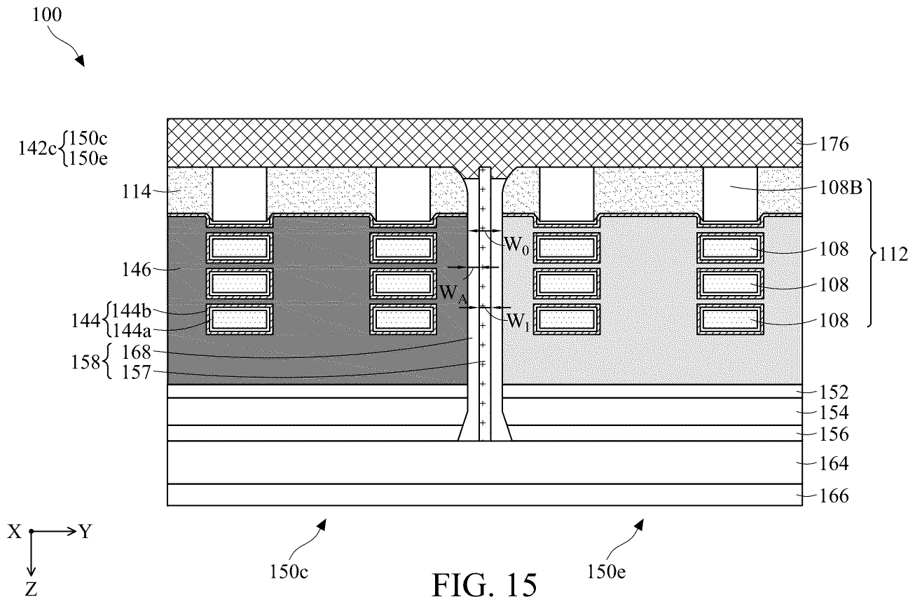

Referring to FIGS. 2 and 15, method 200 includes a block 222 where a dielectric material is deposited on the backside of semiconductor structure 100 and within the opening 172 of air gap 168 to form a seal layer 176. In some embodiments, the seal layer 176 comprises a low-k dielectric material to reduce parasitic capacitance. The dielectric material for seal layer 176 may be deposited using plasma-enhanced chemical vapor deposition (PE-CVD), high-density plasma CVD (HDP-CVD), or other suitable deposition processes. In some embodiments, the dielectric material may include silicon nitride, silicon carbonitride, silicon oxycarbonitride, silicon oxycarbide, or silicon oxynitride. In one embodiment, the low-k dielectric material is deposited using a PE-CVD process, which facilitates the merging of dielectric materials over narrow openings, such as the opening 172 of the air gap 168. The deposition parameters (e.g., pressure, temperature, and gas viscosity) are tuned to maintain the air gap 168 while ensuring that the low-k dielectric material encloses the opening 172 without excessive deposition within the gap itself, thereby preserving the air gap 168 between adjacent gate structures. The portion of the seal layer 176 that closes opening 172 forms a seal plug, effectively sealing air gap 168. In the illustrated embodiment, the seal plug intersects the tapering sidewalls of isolation structure 114, with its top surface positioned above (in the Z direction) the bottom surface of isolation structure 114. Additionally, a bottom portion of filler layer 157 is embedded within the seal plug. Due to the tapering sidewalls of isolation structure 114, the plugged air gap 168 exhibits a varying width: it is wider near the bottom surface of isolation structure 114, narrows near the top surface of the isolation structure 114, then expands between the gate electrode layer 146 of gate structures 150, and further widens above the gate electrode layer 146. The tapering sidewalls of the isolation structure 114 serve as a characteristic feature indicating that the liner layer 155 has been removed from the backside of semiconductor structure 100.

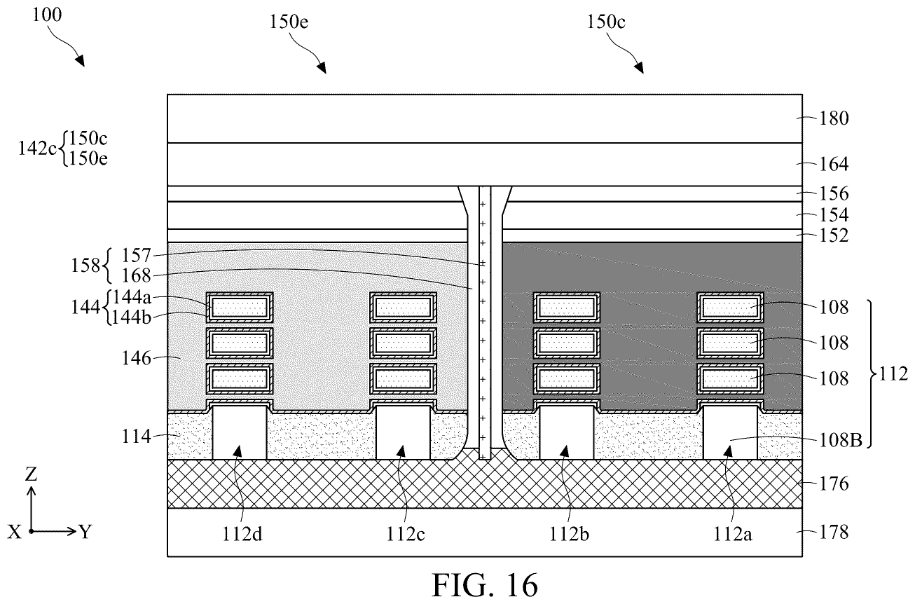

Referring to FIGS. 2 and 16, method 200 includes a block 224 where extra manufacturing operations are performed further toward the final product. Operations at the block 224 may include forming a backside interconnect layer 178 under the seal layer 176, flipping back the semiconductor device 100, and forming a frontside interconnect layer 180 above the second ILD layer 164. The backside interconnect layer 178 includes backside metal lines embedded therein. The backside metal lines electrically connect to the backside of the source/drain features 130 through backside vias (not shown). The backside metal lines may have wider dimension than the first level metal (M0) tracks on the frontside of the semiconductor structure 100, which beneficially reduces the backside routing resistance. Subsequently, the method 200 may remove the carrier 166, form more interconnect layers on the frontside as part of the frontside interconnect layer 180, form a passivation layer (not shown) atop the semiconductor structure 100, dice the wafer into chips, and package the chips.

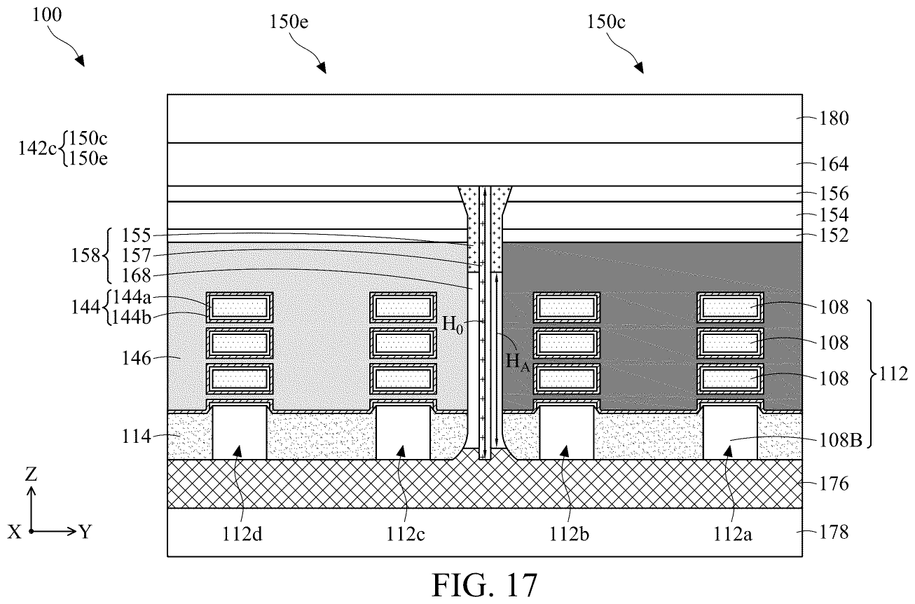

FIG. 17 illustrates an alternative embodiment of the semiconductor structure 100 at the conclusion of operations at the block 224. In the illustrated embodiment, the liner layer 155 is partially removed, such that a top portion of the liner layer 155 still remains above the topmost surface of the channel layers 108. The remaining portion of the liner layer 155, the filler layer 157, and the air gap 168 collectively define the gate-cut structure 158. A ratio of a height H_{A} of the air gap 168 to a height H₀ of the gate-cut structure 158 may range from about 0.3 to about 0.7(0.3<H_{A}/H₀<0.7).

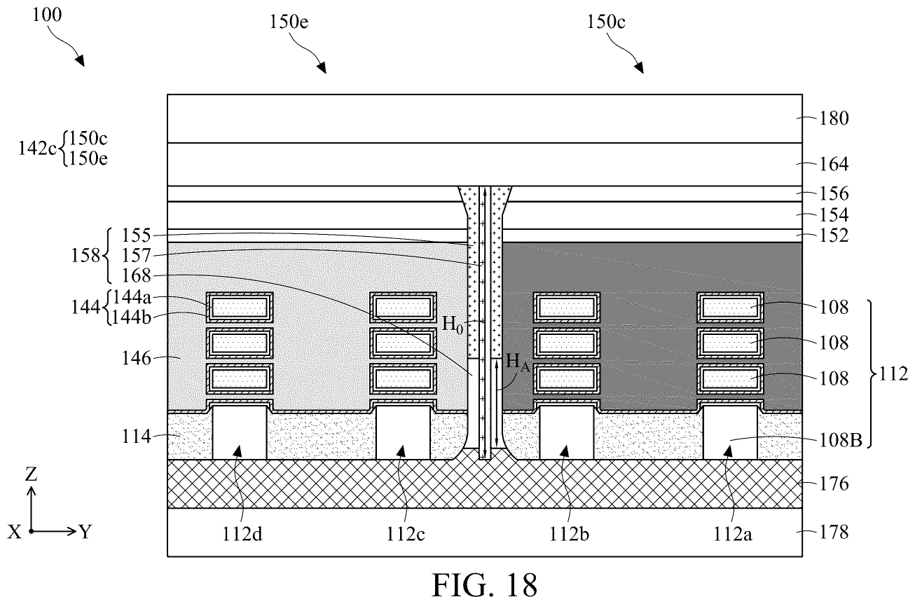

FIG. 18 illustrates another alternative embodiment of the semiconductor structure 100 at the conclusion of operations at the block 224. In the illustrated embodiment, the liner layer 155 is partially removed, such that a top portion of the liner layer 155 still remains and occupies a larger height than the air gap 168. For example, the liner layer 155 may exist between the bottom two of the channel layers 108 (e.g., slightly above the top surface of the bottommost one of the channel layers 108). The remaining portion of the liner layer 155, the filler layer 157, and the air gap 168 collectively define the gate-cut structure 158. A ratio of a height H_{A} of the air gap 168 to a height H₀ of the gate-cut structure 158 may range from about 0.1 to about 0.3 (0.1<H_{A}/H₀<0.3).

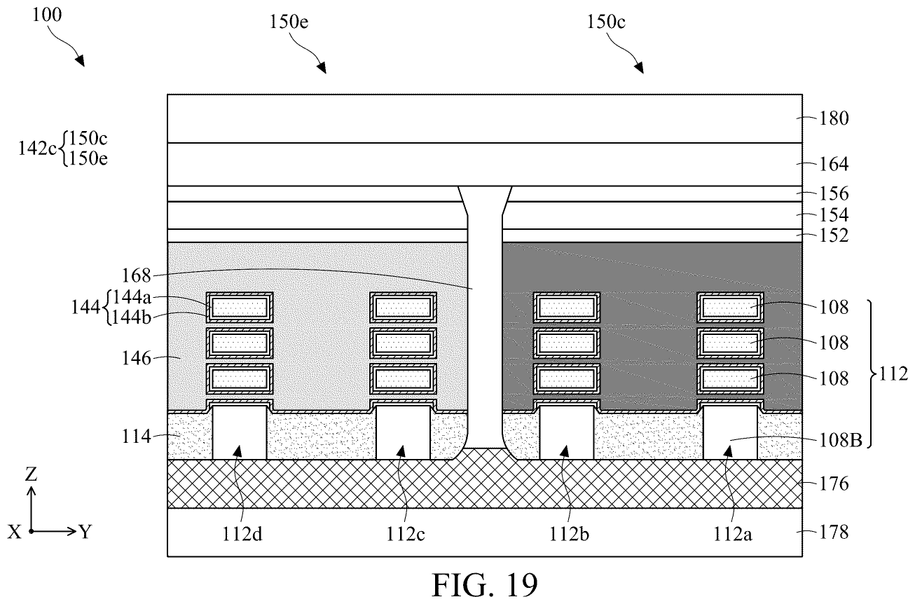

FIG. 19 illustrates another alternative embodiment of the semiconductor structure 100 at the conclusion of operations at the block 224. In the illustrated embodiment, the filler layer 157 is fully removed, such as during the trimming process 174. The complete removal of the filler layer 157 further expands the air gap 168, reducing parasitic capacitance. As a result, the sidewalls of the gate electrode layers 146 of the gate structures 150c and 150e directly face each other. Alternatively, the filler layer 157 may not be formed in the first place. For example, during the deposition of the gate-cut structure 158, the liner layer 155 may be deposited to fully fill the CMG trench 162 without the filler layer 157. The liner layer 155 is then completely removed during the backside removal process to form the air gap 168 as shown in FIG. 19.

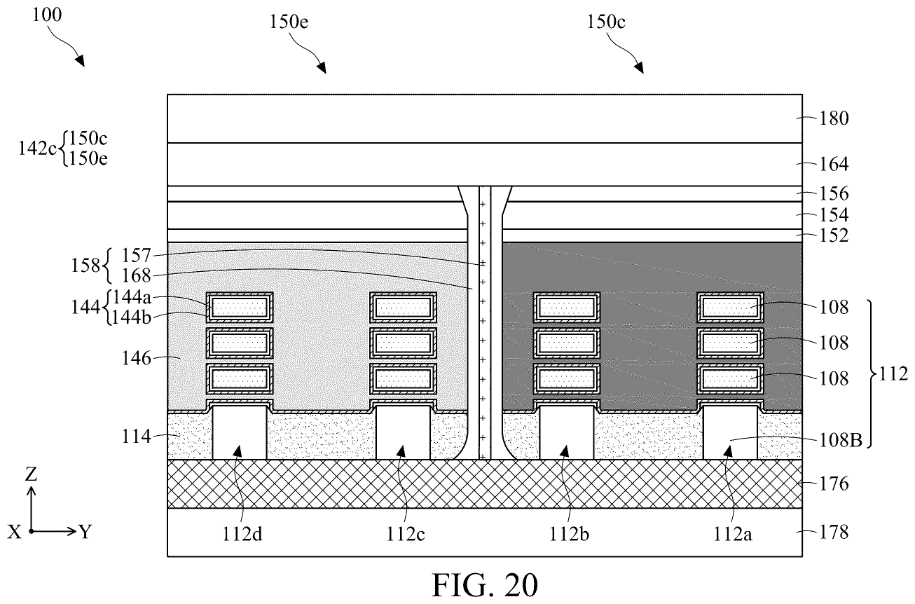

FIG. 20 illustrates another alternative embodiment of the semiconductor structure 100 at the conclusion of operations at the block 224. In the illustrated embodiment, there is no seal plug burying the bottom end of the filler layer 157, and the bottom surface of the filler layer 157 is substantially coplanar with the top surface of the seal layer 176. Such seal layer 176 may be formed by a lamination process. In one example, the seal layer 176 is formed by curing a poly film attached to the backside of the semiconductor structure 100, and the top surface of the dielectric material is substantially coplanar with the bottom surface of the isolation structure 114 without protruding upwardly into the air gap 168. Similarly, in the above alternative embodiments in FIGS. 17 and 18, the bottom surface of the filler layer 157 may also be coplanar with the top surface of the seal layer 176 without being embedded in a seal plug.

With respect to the description provided herein, disclosed are structures and related methods for performing a cut-metal-gate process in forming a gate-cut structure with air gap therein, which helps reducing parasitic capacitance and improving circuit performance. Embodiments of the present disclosure can be readily integrated into existing semiconductor manufacturing processes.

In one exemplary aspect, the present disclosure is directed to a method of fabricating a semiconductor device. The method includes forming a first active region and a second active region over a substrate, the first active region including a first plurality of channel layers vertically stacked above a first fin-shaped base, the second active region including a second plurality of channel layers vertically stacked above a second fin-shape base, the first fin-shaped base protruding from the substrate, the second fin-shaped base protruding from the substrate, forming an isolation structure between the first fin-shaped base and the second fin-shaped base, the isolation structure interfacing a sidewall of the first fin-shaped base and a sidewall of the second fin-shaped base, forming a gate structure across the first active region and the second active region, forming a trench dividing the gate structure into a first segment and a second segment, depositing a dielectric feature in the trench, thinning the substrate and the isolation structure to expose a bottom surface of the dielectric feature, selectively removing a surface layer of the dielectric feature to form an air gap, and depositing a seal layer capping the air gap. In some embodiments, the forming of the trench includes extending the trench through the isolation structure and into a top portion of the substrate. In some embodiments, the air gap exposes sidewalls of the first and second segments of the gate structure. In some embodiments, the dielectric feature includes the surface layer and a center layer. A dielectric constant of the surface layer is larger than that of the center layer. In some embodiments, the surface layer includes a nitride, and the center layer includes an oxide. In some embodiments, after the depositing of the seal layer, a bottom portion of the dielectric feature is embedded in the seal layer. In some embodiments, a top surface of the seal layer is above a bottom surface of the isolation structure. In some embodiments, the selectively removing of the surface layer of the dielectric feature also forms tapering sidewalls of the isolation structure facing the dielectric feature. In some embodiments, the method further includes fully removing the dielectric feature to enlarge the air gap. In some embodiments, a ratio of a height of the air gap to a height of the dielectric feature ranges from about 0.3 to about 0.7.

In another exemplary aspect, the present disclosure is directed to a method. The method includes providing a structure having a frontside and a backside, the structure including a substrate and an isolation structure at the backside and a gate structure at the frontside, depositing a gate spacer on the gate structure, depositing a first interlayer dielectric layer on the gate spacer, recessing a portion of the gate structure to form a trench, the trench extending through the isolation structure and dividing the gate structure into a first segment and a second segment, depositing a liner layer in the trench, depositing a filler layer over the liner layer, depositing a second interlayer dielectric layer over the liner layer and the filler layer, a thickness of the first interlayer dielectric layer being greater than a thickness of the second interlayer dielectric layer, thinning the substrate and the isolation structure to expose the liner layer and the filler layer, selectively removing the liner layer to form an air gap, the air gap exposing the filler layer, and depositing a seal layer at the backside of the structure to plug the air gap. In some embodiments, the method further includes trimming the filler layer to enlarge the air gap. In some embodiments, the method further includes after the selectively removing of the liner layer, selectively removing the filler layer. In some embodiments, the liner layer is a nitride, and the filler layer is an oxide. In some embodiments, after the depositing of the seal layer, a bottom portion of the filler layer is embedded in the seal layer. In some embodiments, the selectively removing of the liner layer removes a bottom portion of the liner layer, and a top portion of the liner layer remains above the air gap.

In another exemplary aspect, the present disclosure is directed to a semiconductor structure. The semiconductor structure includes a plurality of first nanostructures vertically stacked, a plurality of second nanostructures vertically stacked, a first gate segment wrapping around each of the first nanostructures, a second gate segment wrapping around each of the second nanostructures, each of the first and second gate segments comprising a gate dielectric layer and a gate electrode layer over the gate dielectric layer, a gate spacer extending along sidewalls of the first and second gate segments, a dielectric constant of the gate dielectric layer being greater than a dielectric constant of the gate spacer, a dielectric feature disposed between the first and second gate segments, and an air gap laterally disposed between the dielectric feature and each of the first and second gate segments. In some embodiments, a top portion of the air gap is above top surfaces of the first and second gate segments, and a bottom portion of the air gap is below bottom surfaces of the first and second gate segments. In some embodiments, the semiconductor structure further includes a seal layer disposed under the first and second gate segments. A bottom portion of the dielectric feature is embedded in the seal layer. In some embodiments, the semiconductor structure further includes a liner layer disposed above the air gap and laterally disposed between the dielectric feature and each of the first and second gate segments.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
forming a first active region and a second active region over a substrate, the first active region including a first plurality of channel layers vertically stacked above a first fin-shaped base, the second active region including a second plurality of channel layers vertically stacked above a second fin-shape base, the first fin-shaped base protruding from the substrate, the second fin-shaped base protruding from the substrate;
forming an isolation structure between the first fin-shaped base and the second fin-shaped base, the isolation structure interfacing a sidewall of the first fin-shaped base and a sidewall of the second fin-shaped base;
forming a gate structure across the first active region and the second active region;
forming a trench dividing the gate structure into a first segment and a second segment;
depositing a dielectric feature in the trench;
thinning the substrate and the isolation structure to expose a bottom surface of the dielectric feature;
selectively removing a surface layer of the dielectric feature to form an air gap; and
depositing a seal layer capping the air gap.

2. The method of claim 1, wherein the forming of the trench includes extending the trench through the isolation structure and into a top portion of the substrate.

3. The method of claim 1, wherein the air gap exposes sidewalls of the first and second segments of the gate structure.

4. The method of claim 1, wherein the dielectric feature includes the surface layer and a center layer, wherein a dielectric constant of the surface layer is larger than that of the center layer.

5. The method of claim 4, wherein the surface layer includes a nitride, and the center layer includes an oxide.

6. The method of claim 1, wherein after the depositing of the seal layer, a bottom portion of the dielectric feature is embedded in the seal layer.

7. The method of claim 1, wherein a top surface of the seal layer is above a bottom surface of the isolation structure.

8. The method of claim 1, wherein the selectively removing of the surface layer of the dielectric feature also forms tapering sidewalls of the isolation structure facing the dielectric feature.

9. The method of claim 1, further comprising:
fully removing the dielectric feature to enlarge the air gap.

10. The method of claim 1, wherein a ratio of a height of the air gap to a height of the dielectric feature ranges from about 0.3 to about 0.7.

11. A method, comprising:
providing a structure having a frontside and a backside, the structure including a substrate and an isolation structure at the backside and a gate structure at the frontside;
depositing a gate spacer on the gate structure;
depositing a first interlayer dielectric layer on the gate spacer;
recessing a portion of the gate structure to form a trench, the trench extending through the isolation structure and dividing the gate structure into a first segment and a second segment;
depositing a liner layer in the trench;
depositing a filler layer over the liner layer;
depositing a second interlayer dielectric layer over the liner layer and the filler layer, wherein a thickness of the first interlayer dielectric layer is greater than a thickness of the second interlayer dielectric layer;
thinning the substrate and the isolation structure to expose the liner layer and the filler layer;
selectively removing the liner layer to form an air gap, the air gap exposing the filler layer; and
depositing a seal layer at the backside of the structure to plug the air gap.

12. The method of claim 11, further comprising:
trimming the filler layer to enlarge the air gap.

13. The method of claim 11, further comprising:
after the selectively removing of the liner layer, selectively removing the filler layer.

14. The method of claim 11, wherein the liner layer is a nitride, and the filler layer is an oxide.

15. The method of claim 11, wherein after the depositing of the seal layer, a bottom portion of the filler layer is embedded in the seal layer.

16. The method of claim 11, wherein the selectively removing of the liner layer removes a bottom portion of the liner layer, and a top portion of the liner layer remains above the air gap.

17. A semiconductor structure, comprising:
a plurality of first nanostructures vertically stacked;
a plurality of second nanostructures vertically stacked;
a first gate segment wrapping around each of the first nanostructures;
a second gate segment wrapping around each of the second nanostructures, each of the first and second gate segments comprising a gate dielectric layer and a gate electrode layer over the gate dielectric layer;
a gate spacer extending along sidewalls of the first and second gate segments, wherein a dielectric constant of the gate dielectric layer is greater than a dielectric constant of the gate spacer;
a dielectric feature disposed between the first and second gate segments; and
an air gap laterally disposed between the dielectric feature and each of the first and second gate segments.

18. The semiconductor structure of claim 17, wherein a top portion of the air gap is above top surfaces of the first and second gate segments, and a bottom portion of the air gap is below bottom surfaces of the first and second gate segments.

19. The semiconductor structure of claim 17, further comprising:
a seal layer disposed under the first and second gate segments, wherein a bottom portion of the dielectric feature is embedded in the seal layer.

20. The semiconductor structure of claim 17, further comprising:
a liner layer disposed above the air gap and laterally disposed between the dielectric feature and each of the first and second gate segments.
